(19) United States
(12) Patent Application Publication
(10) Pub. No.: US 2025/0273498 A1
(43) Pub. Date: Aug. 28, 2025

(54) EMBEDDED ELECTROSTATIC CHUCK (ESC)

(71) Applicant: Applied Materials, Inc., Santa Clara, CA (US)

(72) Inventors: KARTHIK ELUMALAI, Singapore (SG); ARUNKUMAR TATTI, Haveri (IN); ENG SHENG PEH, Singapore (SG); CHENG SUN, Singapore (SG); ONKARA KORASIDDARAMAIAH, Santa Clara, CA (US); YE Y. LIU, Singapore (SG)

(21) Appl. No.: 18/586,313

(22) Filed: Feb. 23, 2024

(51) Int. Cl. H01L 21/683; H01J 37/32

(52) U.S. Cl. CPC H01L 21/6833; H01J 37/32715; H01J 2237/2007

(57) ABSTRACT

Embodiments disclosed herein may include an apparatus that includes a body with a first surface and a second surface opposite from the first surface. In an embodiment, the body is an electrically conductive material. A hole may be formed into the first surface of the body, and a ceramic plate may be on the second surface of the body. An electrically conductive electrode may be embedded in the ceramic plate. In an embodiment, the apparatus may further include a pin that is electrically conductive and positioned in the hole. The pin may be electrically isolated from the body, and the pin may be electrically coupled to the electrode embedded in the ceramic plate.

### BACKGROUND

### 1) Field

Embodiments relate to the field of semiconductor manufacturing and, in particular, to electrostatic chucks (ESCs) with an RF feed that is electrically isolated from a DC voltage supply.

### 2) Description of Related Art

In semiconductor manufacturing processes, the wafer (e.g., a silicon wafer) or other substrate is coupled to a pedestal during various processes. For example, the wafer may be secured to the pedestal during plasma dicing processes, etching processes, deposition processes, and/or the like. In some embodiments, the wafer is secured to the pedestal through the use of an electrostatic chuck (ESC). The ESC provides an electrostatic force that attracts the wafer to the chuck in order to prevent movement of the wafer during processing.

Typically, the ESC is fed several inputs from an underlying cathode assembly. In existing solutions, an RF feed (for applying an RF bias) and a DC supply (for generating a chucking force) are provided to the ESC through a single input. The coupling of the RF feed and the DC supply can lead to high current leakage. For example, electrical current from the DC supply can leak into the plasma environment.

### SUMMARY

Embodiments disclosed herein may include an apparatus that includes a body with a first surface and a second surface opposite from the first surface. In an embodiment, the body is an electrically conductive material. A hole may be formed into the first surface of the body, and a ceramic plate may be on the second surface of the body. An electrically conductive electrode may be embedded in the ceramic plate. In an embodiment, the apparatus may further include a pin that is electrically conductive and positioned in the hole. The pin may be electrically isolated from the body, and the pin may be electrically coupled to the electrode embedded in the ceramic plate.

Embodiments disclosed herein may include a method of placing a substrate on an electrostatic chuck (ESC). In an embodiment, the ESC has a DC input that is electrically isolated from an RF input. In an embodiment, the method include applying a chucking force to the substrate by activating the DC input, and processing the substrate in a plasma environment during application of an RF bias applied by the RF input. In an embodiment, the method may include releasing the chucking force, and removing the substrate from the ESC.

Embodiments disclosed herein may include a semiconductor processing tool that includes a chamber suitable for maintaining a vacuum environment within the chamber and an electrostatic chuck (ESC) within the chamber. The ESC may include a body that is electrically conductive, and a ceramic plate on the body. An electrically conductive electrode may be embedded within the ceramic plate. In an embodiment, a DC input is electrically coupled to the electrode, and the DC input is electrically isolated from the body. The ESC may further include an RF input that is electrically coupled to the body.

### BRIEF DESCRIPTION OF THE DRAWINGS

FIG. 1A is a perspective view illustration of an electrostatic chuck (ESC) that comprises an metallic body with a ceramic plate with an embedded electrode, in accordance with an embodiment.

FIG. 1B is a cross-sectional illustration of an ESC with a single input for the RF feed and the DC input, in accordance with an embodiment.

FIG. 2A is a cross-sectional illustration of an ESC with a DC input and an RF feed that are electrically isolated from each other, in accordance with an embodiment.

FIG. 2B is a cross-sectional illustration of an ESC with an underlying facility plate for coupling the DC input and the RF feed to the ESC, in accordance with an embodiment.

FIG. 3A is a cross-sectional illustration of a portion of an ESC with openings to accommodate a DC input and an RF feed, in accordance with an embodiment.

FIG. 3B is a zoomed in cross-sectional illustration of the DC input that is electrically isolated from the metallic body of the ESC, in accordance with an embodiment.

FIG. 3C is a cross-sectional illustration of the ESC with the DC input and the RF feed coupled to the ESC, in accordance with an embodiment.

FIG. 3D is a cross-sectional illustration of the ESC with an underlying facility plate for coupling the DC input and the RF feed to the ESC, in accordance with an embodiment.

FIG. 4 is a cross-sectional illustration of a semiconductor processing tool that comprises an ESC with a DC input that is electrically isolated from an RF feed, in accordance with an embodiment.

FIG. 5 is a process flow diagram of a method for processing a substrate with an ESC that comprises a DC input that is electrically isolated from an RF feed, in accordance with an embodiment.

FIG. 6 is a process flow diagram of a method for assembling the ESC to a pedestal with a blind assembly process, in accordance with an embodiment.

FIG. 7 illustrates a block diagram of an exemplary computer system that may be used in conjunction with a processing tool, in accordance with an embodiment.

### DETAILED DESCRIPTION

Embodiments described herein include apparatuses and methods for using an electrostatic chuck (ESC) with an RF feed that is electrically isolated from a DC voltage supply. In the following description, numerous specific details are set forth in order to provide a thorough understanding of embodiments. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

Various embodiments or aspects of the disclosure are described herein. In some implementations, the different embodiments are practiced separately. However, embodiments are not limited to embodiments being practiced in isolation. For example, two or more different embodiments can be combined together in order to be practiced as a single device, process, structure, or the like. The entirety of various embodiments can be combined together in some instances. In other instances, portions of a first embodiment can be combined with portions of one or more different embodiments. For example, a portion of a first embodiment can be combined with a portion of a second embodiment, or a portion of a first embodiment can be combined with a portion of a second embodiment and a portion of a third embodiment.

The embodiments illustrated and discussed in relation to the figures included herein are provided for the purpose of explaining some of the basic principles of the disclosure. However, the scope of this disclosure covers all related, potential, and/or possible, embodiments, even those differing from the idealized and/or illustrative examples presented. This disclosure covers even those embodiments which incorporate and/or utilize modern, future, and/or as of the time of this writing unknown, components, devices, systems, etc., as replacements for the functionally equivalent, analogous, and/or similar, components, devices, systems, etc., used in the embodiments illustrated and/or discussed herein for the purpose of explanation, illustration, and example.

As noted above, existing electrostatic chuck (ESC) structures are susceptible to significant current leakage. The leakage may result from the current (e.g., DC or RF) leaking away from the ESC and coupling with the plasma within a chamber and/or otherwise escaping through other electrical pathways. One problem with leakage is that chucking force is difficult to control. In some instances, current leakage during a processing operation within the chamber may result in dechucking of the wafer. That is, the chucking force dips below a given threshold, and the wafer becomes free to move, bend, or otherwise displace relative to the surface of the ESC. This movement is detrimental because the processing conditions are highly tuned, and the movement may result in non-uniform treatment of the wafer or damage to the wafer or ESC.

To prevent dechucking, the wafer is often “overchucked” so that the chucking force is increased beyond what would otherwise be necessary. This can lead to damage to the wafer and/or damage to the ESC itself. For example, an overchucked wafer can be cracked, chipped, deformed, or otherwise damaged. Overchucking may also lead to excessive wear on the ESC. This may require more frequent repair, replacement, and/or refurbishing of the ESC. As such, the leakage current can lead to increases in cost of ownership of a semiconductor processing tool, and/or an increase in manufacturing costs due to damaged wafers. The presence of leakage current also reduces the efficiency of the system. That is, more energy is needed in order to run a given process when overchucking is necessary to account for leakage. This also increases costs and can generate environmental impact issues.

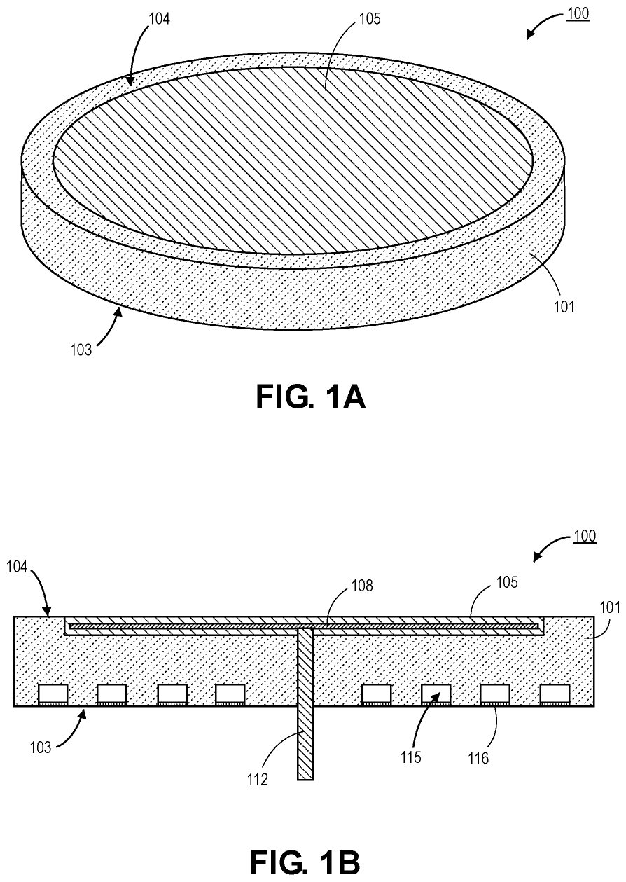

Referring now to FIG. 1A, a perspective view illustration of an ESC 100 is shown, in accordance with an embodiment. In an embodiment, the ESC 100 may comprise a body 101. The body 101 may be an electrically conductive material. For example, the body 101 may comprise aluminum, or the like. The body 101 may have a first surface 103 (e.g., a bottom surface) and a second surface 104 (e.g., a top surface) opposite from the bottom surface. In an embodiment, the body has a cylindrical shape that is suitable for supporting a wafer, such as a standard silicon wafer. For example, a diameter of the body 101 may be at least 200 mm or larger, at least 300 mm or larger, at least 450 mm or larger, or at least 750 mm or larger.

In an embodiment, a ceramic plate 105 may be provided on the second surface 104 of the body 101. The ceramic plate 105 may be set into a recess of the second surface 104 so that the top surface of the ceramic plate 105 is substantially coplanar with a top surface of the body 101. Though, in other embodiments, the ceramic plate 105 may have a top surface above or below the top surface of the body 101.

In an embodiment, the ceramic plate 105 may comprise an electrically conductive electrode (not visible in FIG. 1A). The electrode may be embedded within a thickness of the ceramic plate 105. The electrode is coupled to a DC input in order to generate a chucking force that attracts and secures a wafer (not shown) to the ceramic plate 105. In an embodiment, the ceramic plate may comprise any suitable material, such as aluminum nitride, aluminum oxide, or the like.

Referring now to FIG. 1B, a cross-sectional illustration of the ESC 100 in FIG. 1A is shown, in accordance with an embodiment. As shown, the ceramic plate 105 is set into a recess along the second surface 104 of the body 101. The ceramic plate 105 may also comprise an electrode 108. The electrode 108 may be an electrically conductive material, such as copper or the like. The electrode 108 may be a conductive plate, a conductive mesh, or have any other conductive pattern that is distributed though the ceramic plate 105. In the illustrated embodiment, the electrode 108 is set at a midpoint along a thickness direction of the ceramic plate 105. Though, in other embodiments the electrode 108 may be closer to a top of the ceramic plate 105 or closer to a bottom of the ceramic plate 105. When the electrode 108 is embedded within the ceramic plate 105 as shown in FIG. 1B, the ESC 100 may sometimes be referred to as an embedded ESC 100.

In an embodiment, the electrode 108 may be electrically coupled to an input 112. The input 112 may be an electrically conductive pin that passes through at least a thickness of the body 101. The input 112 may pass through a portion of the ceramic plate 105 in order to directly contact the electrode 108. In other embodiments, the input 112 may be electrically coupled to the electrode 108 by a via (not shown) that passes through at least a portion of the thickness of the ceramic plate 105.

In an embodiment, the input 112 may provide both the DC input and the RF feed to the ESC. For example, DC current supplied to the input 112 may be provided to the electrode 108 in order to generate a chucking force on a wafer (not shown) that is supported by the ESC 100. The input 112 may also receive an RF signal that is transferred to the electrically conductive body 101 of the ESC 100. For example, the body 101 directly contacts the input 112 as well. Since the DC input and the RF feed are not electrically isolated from each other, leakage is more prevalent in the ESC 100 compared to embodiments that will be described in greater detail herein. This may lead to issues with dechucking, excessive energy consumption, and/or the like.

In an embodiment, the ESC 100 may also comprise fluidic channels 115. The fluidic channels 115 may be provided at a bottom of the ESC 100 and sealed with a lid 116. The fluidic channels 115 may be suitable for flowing gas and/or liquid within the body 101. This can be used for cooling or other thermal control of the ESC 100. In some embodiments, multiple zones of fluidic channels 115 may be used in order to provide more refined thermal control across an entire surface of the ESC 100.

As described above, the ESC 100 in FIGS. 1A and 1B suffers from current leakage due to the combined input 112 for the DC current and RF current. Accordingly, embodiments disclosed herein may include an ESC that has a DC input line that is separate from the RF feed. More particularly, the DC voltage applied to the electrode within the ceramic plate can be electrically isolated from the conductive body of the ESC. Similarly, the RF feed can be provided directly to the conductive body of the ESC without being superimposed on the DC input line. Due to the electrical isolation, the leakage current can be reduced.

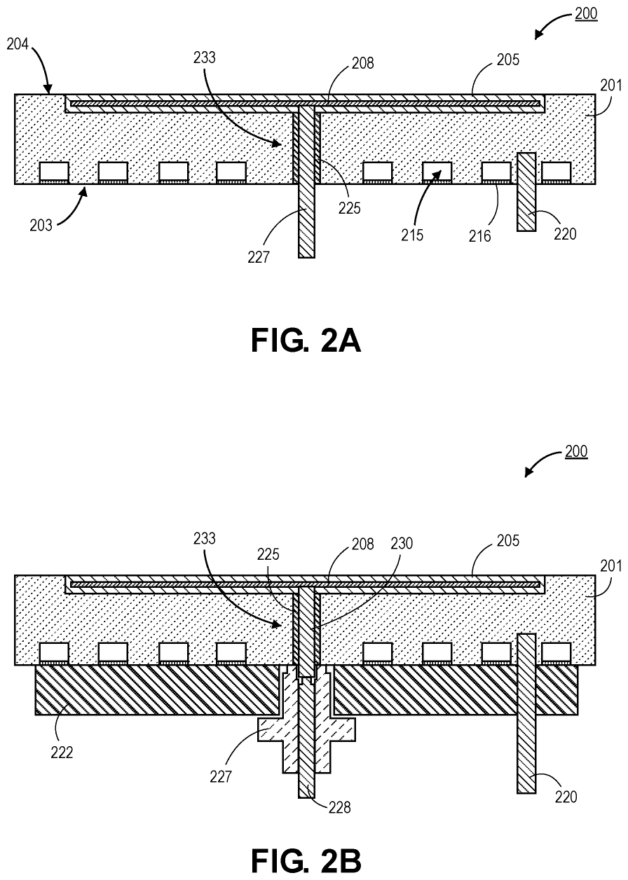

An example of such an ESC 200 is shown in FIG. 2A. FIG. 2A is a cross-sectional illustration of an ESC 200 that comprises an electrically conductive body 201. The electrically conductive body 201 may be aluminum or another suitable metallic material. The conductive body 201 may be cylindrical for supporting wafers in a semiconductor processing environment. For example, the conductive body 201 may have a diameter that is larger than standard wafer form factors (e.g., larger than 200 mm, 300 mm, 450 mm, or the like). In an embodiment, the conductive body 201 may have a first surface 203 (e.g., a bottom surface) and a second surface 204 (e.g., a top surface) that is opposite from the first surface 203.

In an embodiment, the ESC 200 may comprise fluidic channels 215. The fluidic channels 215 may be provided at a bottom of the ESC 200 and sealed with a lid 216. The fluidic channels 215 may be suitable for flowing gas and/or liquid within the body 201. This can be used for cooling or other thermal control of the ESC 200. In some embodiments, multiple zones of fluidic channels 215 may be used in order to provide more refined thermal control across an entire surface of the ESC 200.

In an embodiment, a ceramic plate 205 is provided on the body 201. The ceramic plate 205 may sit in a recess of the second surface 204, or the ceramic plate 205 may be over the first surface 204. The ceramic plate 205 may comprise any suitable ceramic material for ESC chucking, such as aluminum nitride, aluminum oxide, or the like. In an embodiment, an electrode 208 may be embedded in the ceramic plate 205. The electrode 208 may be an electrically conductive material, such as copper or the like. The electrode 208 may be a conductive plate, a conductive mesh, or have any other conductive pattern that is distributed though the ceramic plate 205. In the illustrated embodiment, the electrode 208 is set at a midpoint along a thickness direction of the ceramic plate 205. Though, in other embodiments the electrode 208 may be closer to a top of the ceramic plate 205 or closer to a bottom of the ceramic plate 205. When the electrode 208 is embedded within the ceramic plate 205, as shown in FIG. 2A, the ESC 200 may sometimes be referred to as an embedded ESC 200.

In an embodiment, the electrode 208 may be electrically coupled to a DC input 230. The DC input 230 may be an electrically conductive pin that passes through at least a thickness of the body 201. The DC input 230 may pass through a portion of the ceramic plate 205 in order to directly contact the electrode 208. In other embodiments, the DC input 230 may be electrically coupled to the electrode 208 by a via (not shown) that passes through at least a portion of the thickness of the ceramic plate 205.

In an embodiment, the DC input 230 is electrically isolated from the sidewall of a hole 233 that passes through the body 201. For example, a collar 225 may be provided between the DC input 230 and the sidewall of the hole 233. The collar 225 may be an electrically insulating material, such as a polymer material, a dielectric material, and/or the like. In an embodiment, the collar 225 extends along an entire depth of the hole 233. The presence of the collar 225 prevents the DC current from flowing into the body 201. Accordingly, substantially all of the DC voltage/current is applied to the electrode 208 within the ceramic plate 205. This reduces (or eliminates) leakage from the DC input 230.

In an embodiment, the RF feed 220 is provided as a direct connection to the body 201. The RF feed is spaced away from the DC input 230 and electrically isolated from the DC input 230. As such, control of the RF bias applied to the ESC 200 is separate and independently controllable with respect to the DC bias applied to the electrode 208. As such, electrical leakage of the ESC 200 is improved. This allows for lower chucking powers and improved energy efficiency.

Referring now to FIG. 2B, a cross-sectional illustration of an ESC 200 that is coupled to a facility plate 222 is shown, in accordance with an embodiment. In an embodiment, the facility plate 222 is part of the larger pedestal structure on which the ESC 200 is attached. The facility plate 222 may be an interface structure that allows for the DC input 230 and the RF feed 220 to be passed to regions underlying the ESC 200 and out of the chamber (not shown).

In an embodiment, the facility plate 222 may comprise a metallic material, such as aluminum or the like. In an embodiment, a hole may pass through the facility plate 222 below the DC input 230. In an embodiment, a connector assembly 227 may pass through the hole in the facility plate 222. The connector assembly 227 may comprise an electrically insulating housing that surrounds a pin 228. The pin 228 may be electrically coupled to the DC input 230. In some embodiments, the pin 228 directly contacts the DC input 230. In other embodiments, one or more intervening electrically conductive structures are provided between the pin 228 and the DC input 230.

In an embodiment, the RF feed 220 passes through the facility plate 222 as well. In other embodiments, the RF feed 220 may have a first portion that contacts the facility plate 222, and a second portion that contacts the body 201 of the ESC 200. For example, an electrically conductive rod may contact the facility plate 222, and a screw, a bolt, or the like may extend from the facility plate 222 to the body 201 of the ESC 200. In this way, the rod is electrically coupled to the bolt through the facility plate 222.

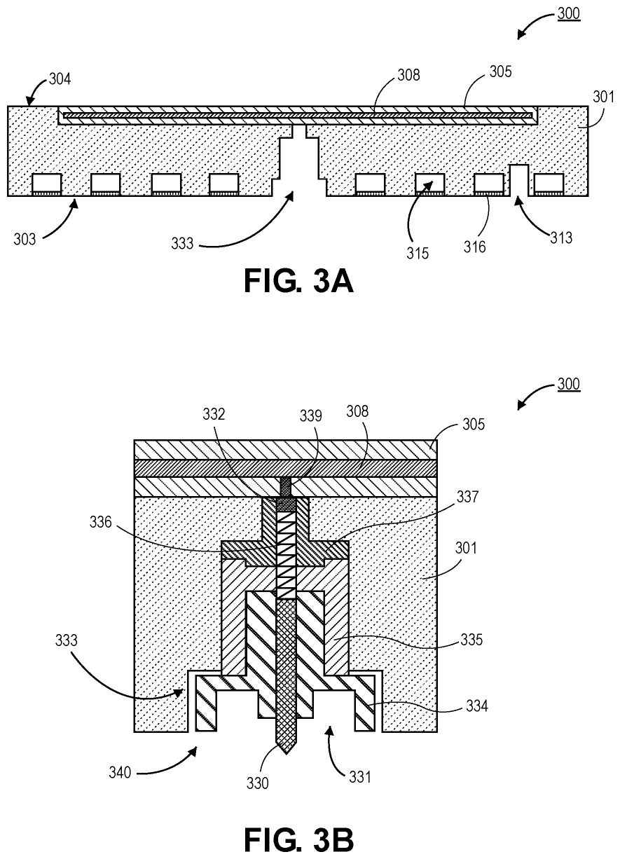

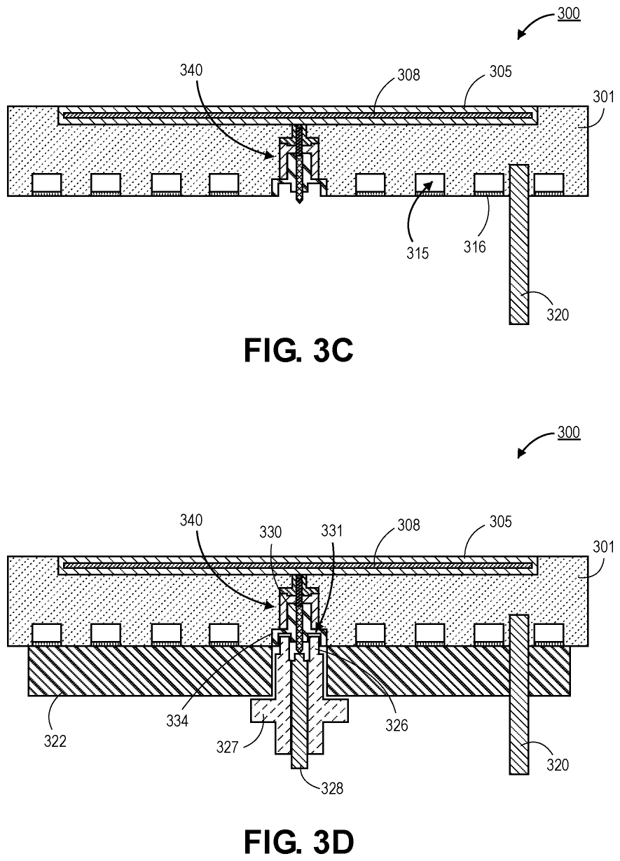

In the embodiment shown in FIGS. 2A and 2B, the DC input 230 is shown as a simple rod that passes through a hole 233 with a constant diameter. Such a construction may be suitable for some designs. However, in cases where the ESC is mounted to the facility plate with a blind assembly process, the design of the DC input may need to be modified. Examples of such embodiments are shown in FIGS. 3A-3D.

Referring now to FIG. 3A, a cross-sectional illustration of a portion of an ESC 300 is shown, in accordance with an embodiment. In an embodiment, the ESC 300 may comprise an electrically conductive body 301. The conductive body 301 may be similar in material and dimension to any of the conductive bodies described in greater detail herein. In an embodiment, the conductive body 301 may have a first surface 303 (e.g., a bottom surface) and a second surface 304 (e.g., a top surface) that is opposite from the first surface 303.

In an embodiment, the ESC 300 may comprise fluidic channels 315. The fluidic channels 315 may be provided at a bottom of the ESC 300, and sealed with a lid 316. The fluidic channels 315 may be suitable for flowing gas and/or liquid within the body 301 to enable thermal control of the ESC 300. In some embodiments, multiple zones of fluidic channels 315 may be used.

In an embodiment, a ceramic plate 305 is provided on the body 301. The ceramic plate 305 may sit in a recess of the second surface 304, or the ceramic plate 305 may be over the first surface 304. The ceramic plate 305 may be similar to any of the ceramic plates described in greater detail herein. In an embodiment, an electrode 308 may be embedded in the ceramic plate 305. The electrode 308 may be similar to any of the electrodes described in greater detail herein.

In an embodiment, a hole 333 may be provided through the body 301 of the ESC 300. The hole 333 may have a non-uniform diameter (or other dimension) through a depth of the hole 333. For example, a diameter of the hole 333 near the first surface 303 may be greater than a diameter of the hole 333 near the second surface 304. In the illustrated embodiment, the hole 333 has a stepped profile. Other embodiments may include a hole 333 with a sloping profile. The hole 333 may be configured to receive the DC input (not shown in FIG. 3A).

In an embodiment, a second hole 313 may be provided into the body 301. The depth of the second hole 313 may be shallower than a depth of the hole 333. In an embodiment, the second hole 313 is configured to provide a coupling point for an RF feed (not shown in FIG. 3A). For example, the second hole 313 may accommodate a bolt, screw, or rod that is carrying the RF bias to the ESC 300.

Referring now to FIG. 3B, a zoomed in illustration of the DC input assembly 340 inserted into the hole 333 of the ESC 300 is shown, in accordance with an embodiment. In an embodiment, the DC input assembly 340 may comprise an electrically conductive rod 330 that is electrically coupled to a DC input 332 by an electrically conductive spring 336. The DC input 332 may be an electrically conductive pad, pin, or the like. The DC input 332 may be electrically coupled to the electrode 308 by a via 339 or the like.

In an embodiment, the rod 330, the spring 336, and the DC input 332 may be surrounded by an electrically insulating collar 334, 335, and 337 to prevent electrical shorting to the body 301. The collar 334, 335, and 337 is shown as being three distinct parts. In other embodiments, a single electrically insulating component can be used as the collar, or a plurality of components can be coupled together to form the collar. As such, a direct and isolated path from the conductive rod 330 to the electrode 308 can be made in order to apply a DC bias to the electrode 308 for generating a chucking force on a substrate (not shown in FIG. 3B).

In an embodiment, the design of the DC input assembly 340 may take into consideration assembly processes. For example, the ESC 300 is often attached to the underlying facility plate (not shown in FIG. 3B) with a blind install. As such, the ability to provide alignment tolerance is beneficial in order to make assembly easier. In some instances, a portion of the collar 334 may include a recess 331 in order to accommodate a connector for the facility plate. The recess 331 may be a ring shaped recess along the bottom surface of the collar 334 that surrounds the rod 330.

The presence of the spring 336 may also be beneficial for the assembly process. Particularly, the spring 336 provides a compressible member that allows for any variation in the placement of the ESC 300 in the Z-dimension to be accommodated. For example, if the ESC 300 is set too “high” the spring 336 expands to provide the proper electrical connection to the electrode 308. Similarly, if the ESC 300 is set too “low” the spring 336 compresses in order reduce the height of the DC input line.

Referring now to FIG. 3C, a cross-sectional illustration of the ESC 300 with the DC input assembly 340 inserted into the body 301 is shown, in accordance with an embodiment. The DC input assembly 340 in FIG. 3C may be substantially similar to the DC input assembly 340 in FIG. 3B. The ESC 300 in FIG. 3C also illustrates the RF feed 320 inserted into the body 301. As shown, the RF feed 320 is an electrically conductive rod, pin, screw, bolt, or the like. The RF feed 320 is configured to provide an RF bias to the body 301 of the ESC 300. The DC input assembly 340 provides electrical isolation between the DC input and the RF feed 320 (i.e., due to the presence of the electrically insulating collar around the rod 330, the spring 336, and the DC input 332).

Referring now to FIG. 3D, a cross-sectional illustration of an ESC 300 that is coupled to a facility plate 322 is shown, in accordance with an embodiment. In an embodiment, the facility plate 322 is part of the larger pedestal structure on which the ESC 300 is attached. The facility plate 322 may be an interface structure that allows for the DC input assembly 340 and the RF feed 320 to be passed to regions underlying the ESC 300 and out of the chamber (not shown).

In an embodiment, the facility plate 322 may comprise a metallic material, such as aluminum or the like. In an embodiment, a hole may pass through the facility plate 322 below the DC input assembly 340. In an embodiment, a connector assembly 327 may pass through the hole in the facility plate 322. The connector assembly 327 may comprise an electrically insulating housing that surrounds a pin 328. The pin 328 may be electrically coupled to the rod 330 of the DC input assembly 340. In some embodiments, the pin 328 directly contacts the rod 330. In other embodiments, one or more intervening electrically conductive structures are provided between the pin 328 and rod 330.

In an embodiment, the connector assembly 327 may comprise a protrusion 326 at an upper edge of the connector assembly 327. The protrusion 326 may be a ring-shaped protrusion that surrounds a perimeter of the pin 328. The protrusion 326 may be sized to insert into the recess 331 of the collar 334. The protrusion 326 and recess 331 interface may be used in order to align the ESC 300 to the facility plate 322 when a blind install or assembly is used.

In an embodiment, the RF feed 320 passes through the facility plate 322 as well. In other embodiments, the RF feed 320 may have a first portion that contacts the facility plate 322, and a second portion that contacts the body 301 of the ESC 300. For example, an electrically conductive rod may contact the facility plate 322, and a screw, a bolt, or the like may extend from the facility plate 322 to the body 301 of the ESC 300. In this way, the rod is electrically coupled to the bolt through the facility plate 322.

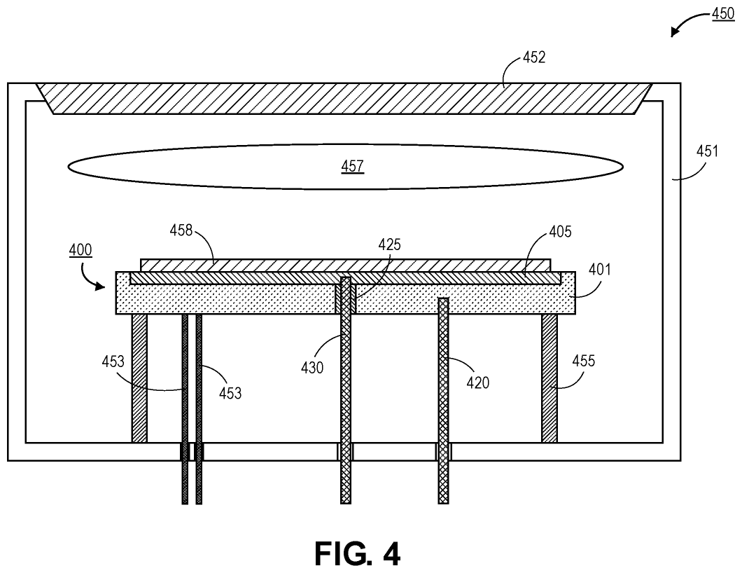

Referring now to FIG. 4, a cross-sectional illustration of a semiconductor processing tool 450 is shown, in accordance with an embodiment. In an embodiment, the semiconductor processing tool 450 may include a plasma processing tool, such as a plasma etching chamber, a plasma dicing chamber, a deposition chamber that uses plasma (e.g., plasma enhanced chemical vapor deposition (PECVD) or plasma enhanced atomic layer deposition (PEALD), etc.), a plasma treatment chamber, or the like.

In an embodiment, the tool 450 may comprise a chamber 451. The chamber 451 may be suitable for supporting a vacuum pressure within the chamber 451 in order to support the generation of a plasma 457. In an embodiment, the chamber 451 may comprise an ESC 400 that is supported over a pedestal 455. The interior of the pedestal 455 (e.g., a facility plate, etc.) is omitted for simplicity. In an embodiment, the ESC 400 may be similar to any of the ESCs described in greater detail herein. For example, the ESC 400 may comprise a metallic body 401 with a ceramic plate 405 on a top surface of the metallic body 401. A DC input 430 may pass through a hole in the body 401, and an electrically insulating collar 425 may electrically isolate the DC input 430 from the body 401. An RF feed 420 may be electrically coupled to the body 401. In an embodiment, fluid feed lines 453 may be provided to the ESC 400 in order to provide gasses or liquids to the ESC 400 for thermal control purposes.

In an embodiment, a substrate 458 may be provided over the ESC 400. The substrate 458 may be chucked to the ESC 400 through the use of the DC input 430 that is coupled to an electrode (not shown) in the ceramic plate 405. The substrate 458 may be a wafer (e.g., a silicon wafer) or any other type of substrate used in a semiconductor processing environment.

In an embodiment, a showerhead 452 may be provided as a lid to the chamber 451 that is opposite from the ESC 400. Processing gasses may be flown into the chamber 451 through the showerhead 452. The showerhead 452 may be biased with RF or microwave frequencies in order to ignite the plasma 457 within the chamber 451.

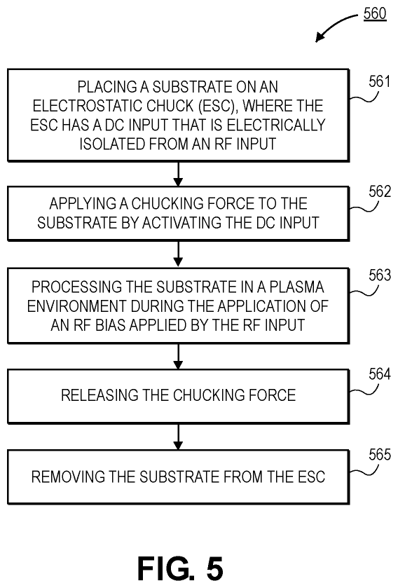

Referring now to FIG. 5, a process flow diagram of process 560 for processing a substrate with a semiconductor tool that includes an ESC with a DC input that is electrically isolated from an RF input is shown, in accordance with an embodiment. In an embodiment, the process 560 begins with operation 561, which comprises placing a substrate on an ESC, where the ESC has a DC input that is electrically isolated from an RF input. The ESC used in process 560 may be similar to any of the ESCs described in greater detail herein.

In an embodiment, the process 560 may continue with operation 562, which comprises applying a chucking force to the substrate by activating the DC input. Since the DC input is electrically isolated from a remainder of the ESC, the chucking force needed to secure the substrate is reduced compared to existing ESC devices. This also allows for lower current leakage and provides a more efficient tool.

In an embodiment, the process 560 may continue with operation 563, which comprises processing the substrate in a plasma environment during an application of an RF bias applied by the RF input. In an embodiment, the processing may include a plasma etching process, a plasma dicing process, or any other treatment process. In an embodiment, the chucking force to the substrate remains substantially constant during the processing of the substrate. Since there is substantially no leakage, the uniform chucking force can be maintained without changing a DC voltage of the DC input.

In an embodiment, the process 560 may continue with operation 564, which comprises releasing the chucking force. In an embodiment, the chucking force may be released by reducing a voltage of the DC input. After the chucking force is released, the process 560 may continue with operation 565. Operation 565 may comprise removing the substrate from the ESC. The substrate may be removed by a wafer handling robot or the like.

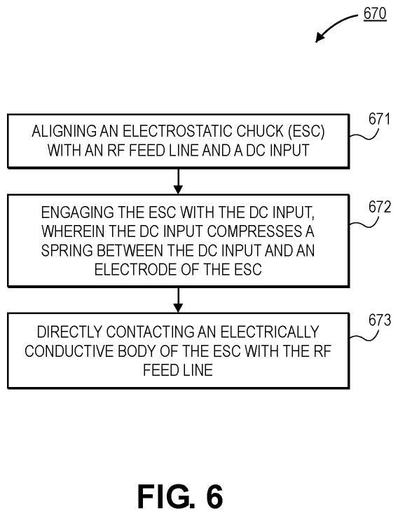

Referring now to FIG. 6, a process flow diagram of a process 670 for assembling an ESC to a pedestal is shown, in accordance with an embodiment. In an embodiment, the process 670 may begin with operation 671, which comprises aligning the ESC with an RF feed line and a DC input. The ESC may have a first hole that is aligned over the DC input and a second hole that is aligned over the RF feed line.

In an embodiment, the process 670 may continue with operation 672, which comprises engaging the ESC with the DC input. In an embodiment, engaging the DC input with the ESC compresses a spring between the DC input and an electrode of the ESC. In an embodiment, the compression of the spring improves the electrical connection between the DC input and the electrode of the ESC.

In an embodiment, the process 670 may continue with operation 673, which comprises directly contacting an electrically conductive body of the ESC with the RF feed line. In an embodiment, the RF feed line provides an RF bias to the ESC during processing. In an embodiment, the RF feed line and the DC input are electrically isolated from each other. For example, the DC input may be separated from the conductive body of the ESC by an electrically insulating collar, similar to those described in greater detail herein.

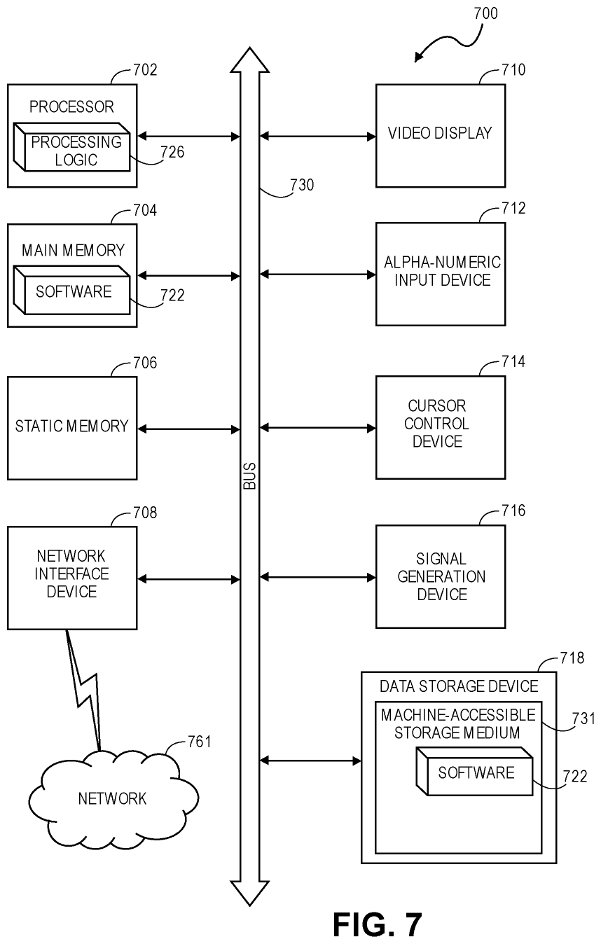

Referring now to FIG. 7, a block diagram of an exemplary computer system 700 of a processing tool is illustrated in accordance with an embodiment. In an embodiment, computer system 700 is coupled to and controls processing in the processing tool. Computer system 700 may be connected (e.g., networked) to other machines in a Local Area Network (LAN), an intranet, an extranet, or the Internet. Computer system 700 may operate in the capacity of a server or a client machine in a client-server network environment, or as a peer machine in a peer-to-peer (or distributed) network environment. Computer system 700 may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated for computer system 700, the term “machine” shall also be taken to include any collection of machines (e.g., computers) that individually or jointly execute a set (or multiple sets) of instructions to perform any one or more of the methodologies described herein.

Computer system 700 may include a computer program product, or software 722, having a non-transitory machine-readable medium having stored thereon instructions, which may be used to program computer system 700 (or other electronic devices) to perform a process according to embodiments. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

In an embodiment, computer system 700 includes a system processor 702, a main memory 704 (e.g., read-only memory (ROM), flash memory, dynamic random access memory (DRAM) such as synchronous DRAM (SDRAM) or Rambus DRAM (RDRAM), etc.), a static memory 706 (e.g., flash memory, static random access memory (SRAM), etc.), and a secondary memory 718 (e.g., a data storage device), which communicate with each other via a bus 730.

System processor 702 represents one or more general-purpose processing devices such as a microsystem processor, central processing unit, or the like. More particularly, the system processor may be a complex instruction set computing (CISC) microsystem processor, reduced instruction set computing (RISC) microsystem processor, very long instruction word (VLIW) microsystem processor, a system processor implementing other instruction sets, or system processors implementing a combination of instruction sets. System processor 702 may also be one or more special-purpose processing devices such as an application specific integrated circuit (ASIC), a field programmable gate array (FPGA), a digital signal system processor (DSP), network system processor, or the like. System processor 702 is configured to execute the processing logic 726 for performing the operations described herein.

The computer system 700 may further include a system network interface device 708 for communicating with other devices or machines. The computer system 700 may also include a video display unit 710 (e.g., a liquid crystal display (LCD), a light emitting diode display (LED), or a cathode ray tube (CRT)), an alphanumeric input device 712 (e.g., a keyboard), a cursor control device 714 (e.g., a mouse), and a signal generation device 716 (e.g., a speaker).

The secondary memory 718 may include a machine-accessible storage medium 731 (or more specifically a computer-readable storage medium) on which is stored one or more sets of instructions (e.g., software 722) embodying any one or more of the methodologies or functions described herein. The software 722 may also reside, completely or at least partially, within the main memory 704 and/or within the system processor 702 during execution thereof by the computer system 700, the main memory 704 and the system processor 702 also constituting machine-readable storage media. The software 722 may further be transmitted or received over a network 761 via the system network interface device 708. In an embodiment, the network interface device 708 may operate using RF coupling, optical coupling, acoustic coupling, or inductive coupling.

While the machine-accessible storage medium 731 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies. The term “machine-readable storage medium” shall accordingly be taken to include, but not be limited to, solid-state memories, and optical and magnetic media.

In the foregoing specification, specific exemplary embodiments have been described. It will be evident that various modifications may be made thereto without departing from the scope of the following claims. The specification and drawings are, accordingly, to be regarded in an illustrative sense rather than a restrictive sense.

What is claimed is:

1. An apparatus, comprising:
a body with a first surface and a second surface opposite from the first surface, wherein the body comprises an electrically conductive material;
a hole into the first surface of the body;
a ceramic plate on the second surface of the body, wherein an electrically conductive electrode is embedded in the ceramic plate; and
a pin that is electrically conductive, wherein the pin is positioned in the hole and the pin is electrically isolated from the body, and wherein the pin is electrically coupled to the electrode embedded in the ceramic plate.

2. The apparatus of claim 1, wherein the pin is electrically coupled to the electrode by a spring within the hole.

3. The apparatus of claim 1, wherein the pin is electrically isolated from the body by a collar that is electrically insulating.

4. The apparatus of claim 3, wherein a bottom surface of the collar has a ring shaped recess.

5. The apparatus of claim 3, wherein the collar comprises two or more components.

6. The apparatus of claim 1, further comprising an input coupled to the body, wherein the input is configured to apply an RF bias to the body.

7. The apparatus of claim 1, wherein the pin is configured to apply a DC voltage to the electrode embedded in the ceramic plate.

8. The apparatus of claim 1, further comprising:
a channel configured to flow a gas or fluid within the body.

9. The apparatus of claim 1, wherein the body has a diameter greater than 200 mm.

10. The apparatus of claim 1, wherein the hole has a non-uniform diameter through the body.

11. A method, comprising:
placing a substrate on an electrostatic chuck (ESC), wherein the ESC has a DC input that is electrically isolated from an RF input;
applying a chucking force to the substrate by activating the DC input;
processing the substrate in a plasma environment during application of an RF bias applied by the RF input;
releasing the chucking force; and
removing the substrate from the ESC.

12. The method of claim 11, wherein processing the substrate comprises a plasma dicing operation, an etching operation, or a deposition operation.

13. The method of claim 11, wherein the DC input comprises a pin that is surrounded by an electrically insulating collar.

14. The method of claim 13, wherein the DC input further comprises a spring between the pin and an electrode embedded in the ESC.

15. The method of claim 11, wherein the chucking force to the substrate remains substantially constant during the processing of the substrate without changing a DC voltage of the DC input.

16. The method of claim 11, wherein the ESC comprises at least two backside gas zones.

17. The method of claim 11, wherein the RF input biases an electrically conductive body of the ESC.

18. A semiconductor processing tool, comprising:
a chamber suitable for maintaining a vacuum environment within the chamber; and
an electrostatic chuck (ESC) within the chamber, wherein the ESC comprises:
a body that is electrically conductive;
a ceramic plate on the body, wherein an electrically conductive electrode is embedded within the ceramic plate;
a DC input electrically coupled to the electrode, and wherein the DC input is electrically isolated from the body; and
an RF input electrically coupled to the body.

19. The semiconductor processing tool of claim 18, wherein the semiconductor processing tool is configured for plasma dicing operations, etching operations, or deposition operations.

20. The semiconductor processing tool of claim 18, wherein the DC input comprises a pin, and wherein the pin is electrically coupled to the electrode by at least a spring.
